(19) United States
(12) Patent Application Publication
(10) Pub. No.: US 2010/0005162 A1
(43) Pub. Date: Jan. 7, 2010

(54) BYPASS CONTROL MODULE AND NETWORK MANAGEMENT APPARATUS THEREOF AND CONTROL METHOD OF THE NETWORK SYSTEM

(75) Inventors: Heng-Chia Wu, Taipei City (TW); Jiun-Chin Wang, Taipei City (TW)

Correspondence Address: J C PATENTS, 4 VENTURE, SUITE 250, IRVINE, CA, 92618, US

(73) Assignee: INVENTEC CORPORATION, Taipei City (TW)

(21) Appl. No.: 12/195,993

(22) Filed: Aug. 21, 2008

(30) Foreign Application Priority Data
Jul. 4, 2008 (TW) 97125232

(51) Int. Cl. G06F 15/173; H03K 3/00; H03K 3/356

(52) U.S. Cl. 709/223; 327/218; 327/208

(57) ABSTRACT

A bypass control module includes a logic circuit and a condition circuit. The logic circuit produces a logic output signal according to a state of a system power received from a network system and a state of at least one first control signal. The condition circuit is coupled to the logic circuit for producing a condition signal and determining a condition signal state according to the logic output state. The said network system selects one of the data transmission paths according to the logic circuit state for data transmission.

### CROSS-REFERENCE TO RELATED APPLICATION

This application claims the priority benefit of Taiwan application serial no. 97125232, filed on Jul. 4, 2008. The entirety of the above-mentioned patent application is hereby incorporated by reference herein and made a part of this specification.

### BACKGROUND OF THE INVENTION

1. Field of the Invention

The present invention relates to a network management apparatus. More particularly, the present invention relates to a bypass control module of a network management apparatus.

2. Description of Related Art

With development of technology, network is widely applied to people's daily life for greatly improving a life convenience, such as emails, data transmission, online purchasing, resource sharing, online studying and searching, etc.

Therefore, regardless of a cable or a wireless network system, stability of network connections is quite essential. In a conventional network system, if an abnormal situation that influences the network connection is occurred, for example, instability of input power or hardware malfunction, the system may activate a LAN bypass function to keep the network smooth. However, since the present LAN bypass function is to keep the network smooth by controlling a relay via a software or an operating system (OS), when the system is turned off, a control signal of a relay power may not be timely switched due to a time difference, so that a malfunction thereof can be occurred.

### SUMMARY OF THE INVENTION

Accordingly, the present invention is directed to a bypass control module, which may avoid miss operation of a relay controlled by a system due to a sudden disappearance of a power supply.

The present invention is directed to a network management apparatus and a management method thereof, by which miss operation of a relay thereof can be avoided.

The present invention provides a bypass control module for switching a plurality of data transmission paths within a network system. The bypass control module includes a logic circuit and a condition circuit. The logic circuit generates a logic output signal according to a state of a system power received by the network system and a state of at least one first control signal. The condition circuit is coupled to the logic circuit for outputting a condition signal and determining a state of the condition signal according to a state of the logic output signal. The network system selects one of the data transmission paths according to the state of the logic circuit for transmitting data.

Moreover, in the bypass control module of the present invention, the logic circuit further determines the state of the logic output signal according to a state of a second control signal.

In an embodiment of the present invention, the logic circuit of the bypass control module includes an OR gate and a D flip-flop. The OR gate respectively receives the first control signal and the second control signal, and outputs an OR gate signal. The D flip-flop has a flip-flop input terminal, a clock terminal and a flip-flop output terminal, wherein the flip-flop input terminal is coupled to the OR gate for receiving the OR gate signal. The clock terminal receives the system power, and when a state of the system power is switched from a high level to a low level, the OR gate signal is output from the flip-flop output terminal to the condition circuit to serve as the logic output signal.

In an embodiment of the present invention, the condition circuit of the bypass control module includes a transistor. A source of the transistor is coupled to the ground, a gate thereof receives the logic output signal, and a drain thereof outputs the condition signal.

According to another aspect, the present invention provides a network management apparatus which is adapted to a network system and is used for connecting a plurality of client hosts to a server. The network management apparatus includes a logic circuit, a condition circuit and a plurality of switching modules. The logic circuit generates a logic output signal according to a state of a system power and a state of at least one first control signal. The condition circuit is coupled to the logic circuit for outputting a condition signal and determining a state of the logic circuit according to a state of the logic output signal. Moreover, the plurality of switching modules is respectively coupled to the client hosts and the server, and respectively has a first transmission terminal and a plurality of second transmission terminals. Each of the switching modules is coupled to a next switching module via the second transmission terminals, and the switching modules are further coupled to the condition circuit for determining to couple the first transmission terminal of each switching module to one of the second transmission terminals of each switching module according to a state of the condition signal.

Moreover, in the network management apparatus of the present invention, the logic circuit further determines the state of the logic output signal according to a state of a second control signal.

In an embodiment of the present invention, the logic circuit of the network management apparatus includes an OR gate and a D flip-flop. The OR gate respectively receives the first control signal and the second control signal, and outputs an OR gate signal. The D flip-flop has a flip-flop input terminal, a clock- terminal and a flip-flop output terminal, wherein the flip-flop input terminal is coupled to the OR gate for receiving the OR gate signal. The clock terminal receives the system power, when a state of the system power is switched from a high level to a low level, the OR gate signal is output from the flip-flop output terminal to the condition circuit to serve as the logic output signal.

In an embodiment of the present invention, the network management apparatus further includes a motherboard controller and an input output control unit. The motherboard controller determines whether to output the first control signal according to an operation of a user. The input output control unit includes a counter, wherein the counter starts to count time when the network system is abnormal, when a counted time reaches a predetermined time, the input output control unit outputs the second control signal.

Moreover, in the network management apparatus of the present invention, the first transmission terminal of each of the switching modules is coupled to one of the client hosts via an RJ 45 interface.

In an embodiment of the present invention, the network management apparatus further includes a plurality of converters and a transceiving unit. : Each of the converters is coupled to the corresponding switching module via one of the second transmission terminals of each of the switching modules. The transceiving unit is coupled to the converters via an interface, and is coupled to the server.

Moreover, in the network management apparatus of the present invention, the interface is a media-related interface (MDI).

According to another aspect, the present invention also provides a method for managing a network system. The network system is operated according to a system power. The method for managing the network system includes the following steps. First, a plurality of second transmission paths is provided for mutually connecting the client hosts. Next, a physical logical circuit is provided. Next, when the network system is turned off, the physical logical circuit selects the first transmission path or the second transmission path for transmitting data.

According to the method for managing the network system, step of judging whether the network system is turned off includes detecting whether a state of the system power is switched from a high level to a low level. When the network system is turned off, the physical logical circuit further selects the first transmission path or the second transmission path according to an operation of a user for transmitting data.

In an embodiment of the present invention, the method for managing the network system further includes judging whether the network system is abnormal, and starting to count time if the network is abnormal, wherein when a counted time reaches a predetermined time, the physical logical circuit selects the first transmission path for transmitting data.

In the present invention, since the physical logical circuit is applied to manage states of the switching modules, miss operation of the switching modules can be avoided.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a block diagram illustrating a network system according to an embodiment of the present invention.

FIG. 2 is a functional block diagram of a network management apparatus according to an embodiment of the present invention.

FIG. 3 is a circuit diagram of a bypass control module according to an embodiment of the present invention.

FIG. 4 is a flowchart illustrating a method for managing a network system according to an embodiment of the present invention.

FIG. 5 is a flowchart illustrating a method for managing a network system according to an embodiment of the present invention.

### DESCRIPTION OF EMBODIMENTS

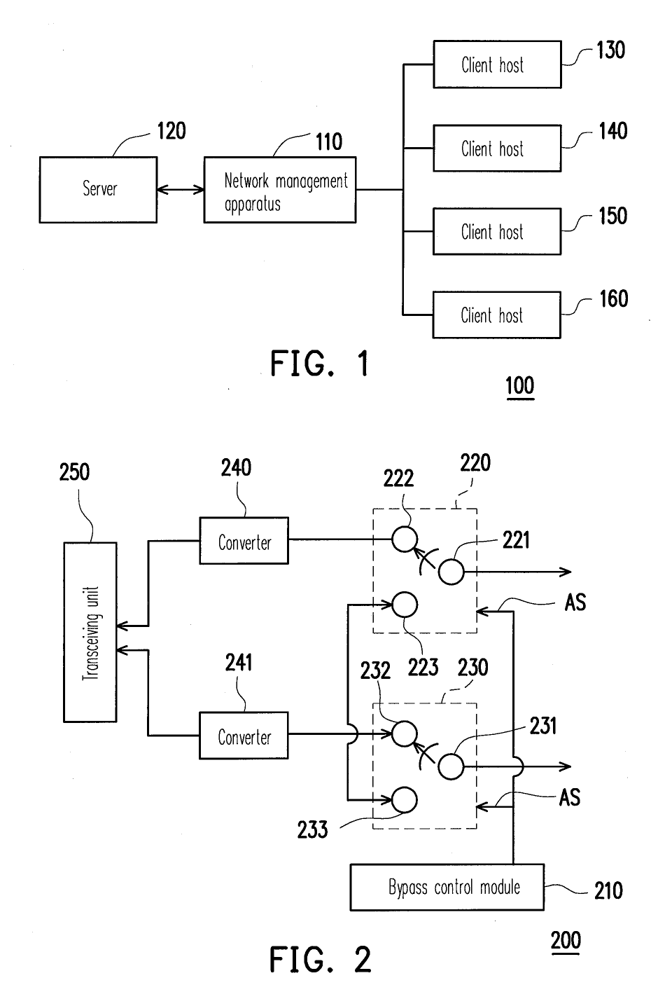

FIG. 1 is a block diagram illustrating a network system according to an embodiment of the present invention. Referring to FIG. 1, the network system 100 includes a network management apparatus 110, a server 120 and client hosts 130, 140, 150 and 160. The server 120 and the client hosts 130, 140, 150 and 160 are respectively coupled to the network management apparatus 110. By such means, the client hosts 130, 140, 150 and 160 then may access data of the server 120 via the network management apparatus 110. In the present embodiment, the network management apparatus 110 may have a plurality of RJ 45 interfaces, and the client hosts 130, 140, 150 and 160 are coupled to the network management apparatus 110 via the RJ 45 interfaces.

The network management apparatus 110 may provide a plurality of data transmission paths for each of the client hosts 130, 140, 150 and 160. In some embodiments of the present invention, the predetermined data transmission paths are connected to the server 120, while in some other embodiments, the network management apparatus 110 can also activate a LAN bypass function to provide the paths for mutually connecting the client hosts, for example, connecting the client hosts 130 and 140 or connecting the client hosts 140 and 150.

FIG. 2 is a functional block diagram of a network management apparatus according to an embodiment of the present invention. Referring to FIG. 2, the network management apparatus 200 of the present embodiment includes a bypass control module 210, switching modules 220 and 230, converters 240 and 241, and a transceiving unit 250. In the present embodiment, the switching modules 220 and 230 respectively have a first terminal 221 and a first terminal 231, and a plurality of second terminals 222, 223, 232 and 233. Each of the switching modules is coupled to a corresponding converter via a corresponding second terminal. For example, the switching module 220 can be coupled to the converter 240 via the second terminal 222, and the switching module 230 can be coupled to the converter 241 via the second terminal 232. Moreover, the converters 240 and 241 are coupled to the transceiving unit 250. Generally, the transceiving unit 250 is for example, coupled to the server 120 of FIG. 1. In an embodiment, the transceiving unit 250 can be coupled to the converters 240 and 241 via an interface, and the interface is a media-related interface. Moreover, the transceiving unit 250 is for example, a PHY-Marvell-88E1121 integrated circuit.

Moreover, the switching modules 220 and 230 can also be mutually connected via other second terminals. For example, the switching module 220 can be coupled to the second terminal 233 of the switching module 230 via the second terminal 223. The first terminals 221 and 231 of the switching modules 220 and 230 can be for example, coupled to the client hosts 130, 140, 150 and 160 of FIG. 1 via interfaces such as the RJ 45 interfaces. By such means, the client hosts connected to the switching modules 220 and 230 then have the mutually connected data transmission paths.

Particularly, the switching modules 220 and 230 can also be coupled to the bypass control module 210. In the present embodiment, the bypass control module 210 receives a system power to control the switching modules 220 and 230 for respectively connecting the first terminals 221 and 231 to the second terminals 222 and 232, or to the second terminals 223 and 233.

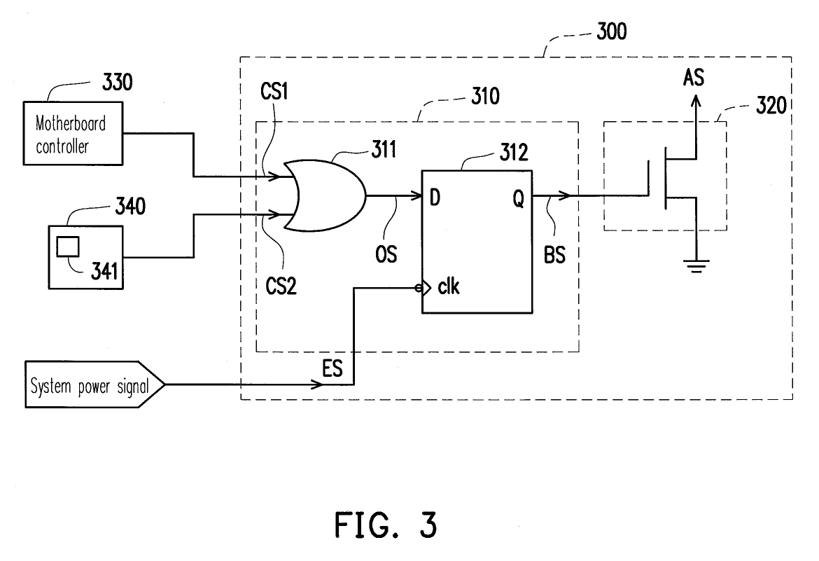

FIG. 3 is a circuit diagram of a bypass control module according to an embodiment of the present invention. Referring to FIG. 3, the bypass control module 300 includes a logic circuit 310 and a condition circuit 320, wherein the logic circuit 310 is coupled to the condition circuit 320. The logic circuit 310 receives at least one first control signal CS1 and a system power signal ES. In the present embodiment, the logic circuit 310 further receives a second control signal CS2. By such means, the logic circuit 310 determines whether to output a logic output signal BS to the condition circuit 320 according to states of the first control signal CS1, the second control signal CS2 and the system power signal ES.

The logic circuit 310 includes an OR gate 311 and a D flip-flop 312. The OR gate 311 receives the control signals CS1 and CS2, and outputs an OR gate signal OS to the D flip-flop 312. The D flip-flop 312 has a flip-flop input terminal D, a clock terminal clk and a flip-flop output terminal Q. The flip-flop input terminal D of the D flip-flop 312 is coupled to the output terminal of the OR gate 311 for receiving the OR gate signal OS. The clock terminal clk of the D flip-flop 312 receives the system power signal ES, and the flip-flop output terminal Q is coupled to the condition circuit 320.

The condition circuit 320 can be implemented by a transistor, wherein a gate of the transistor is coupled to the flip-flop output terminal Q of the logic circuit 310, a source of the transistor is coupled to the ground, and a drain of the transistor is for example, coupled to the switching modules 220 and 230 of FIG. 2. By such means, the condition circuit 320 can determine whether to output a condition signal AS from the drain to the switching modules 220 and 230 according to a logic output signal BS.

Referring to FIG. 2 and FIG. 3, in the present embodiment, the first control signal CS1 is output from the motherboard controller 330, and the second control signal CS2 is output from an input output control unit 340. Moreover, the D flip-flop 312 may have a characteristic of negative edge triggering. Therefore, when the system is turned off, the system power signal ES is switched from the high level to the low level, and a negative edge is generated to the clock terminal clk of the D flip-flop 312. Now, the D flip-flop 312 outputs the OR gate signal OS to serve as the logic output signal BS to the condition circuit 320. In the following content, several embodiments are provided for describing operations of the D flip-flop 312.

### First Situation

When the first terminals 221 and 231 of the switching modules 220 and 230 are about to be coupled to the second terminals 223 and 233, the motherboard controller 330 then may output the first control signal CS1 with the high level to the OR gate 311. Now, the OR gate signal OS output from the OR gate 311 has a high level state due to the state of the first control signal CS1. However, during normal operation of the system, the system power signal ES maintains the high level, so that the OR gate signal OS can be latched at flip-flop input terminal D of the D flip-flop 312.

Now, if the system is turned off, the system power signal ES is then switched from the high level to the low level, and a signal with a negative edge is provided to the clock terminal clk. Now, the D flip-flop 312 takes the high level OR gate signal OS originally latched at the flip-flop input terminal D as the logic output signal BS, and transmits it to the gate of the transistor of the condition circuit 320 for enabling the condition circuit 320, so as to pull down a state of the condition signal AS to the ground level. When the switching modules 220 and 230 receive the ground level condition signal AS, the first terminals 221 and 231 are respectively connected to the second terminals 223 and 233, so as to activate the bypass function.

### Second Situation

In some embodiments, the input output control unit 340 has a counter 341. When the system is abnormal, the counter 341 starts to count time and generates a time counting value. When the time counting value reaches a predetermined time, the input output control unit 340 outputs a low level second control signal CS2 to the OR gate 311. Similarly, the OR gate signal OS has a low level state due to the state of the second control signal CS2, and is latched at the flip-flop input terminal D of the D flip-flop 312.

Now, if the system is turned off, and the system power signal ES is switched from the high level to the low level, the D flip-flop 312 then takes the low level OR gate signal OS originally latched at the flip-flop input terminal D as the logic output signal BS, and transmits it to the gate of the transistor of the condition circuit 320 for disabling the condition circuit 320, so as to disable the condition signal AS. When the condition signal AS is disabled, the first terminals 221 and 231 of the switching modules 220 and 230 are then respectively connected to the second terminals 222 and 232.

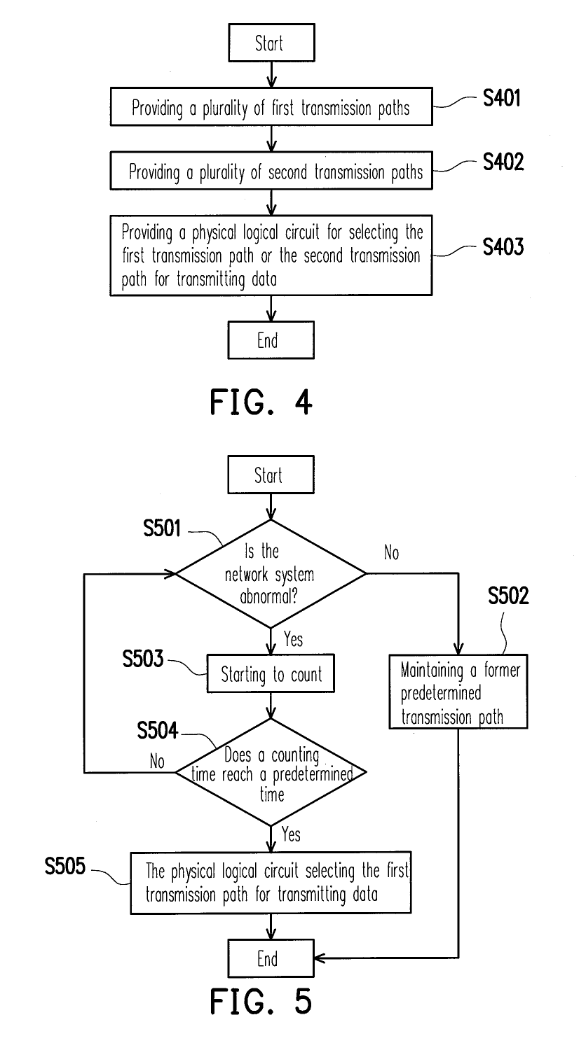

According to the above description, the present invention provides a method for managing a network system, and a flowchart thereof is shown as FIG. 4. Referring to FIG. 4, the method for managing the network system (for example, the network system 100 of FIG. 1) is as follows. In step S401, a plurality of first transmission paths is provided for connecting the client hosts to the server. The so-called first transmission path of the present embodiment is for example the data transmission path formed between the first terminal 221 and the second terminal 222 of the switching module 220 of FIG. 2.

Moreover, in step S402, a plurality of second transmission paths is provided, for example, the data transmission paths formed between the first terminals 221 and 231 and the second terminals 223 and 233 of the switching modules 220 and 230 of FIG. 2. The second transmission paths can be used for mutually connecting the client hosts Particularly, in step S403, a physical logical circuit (for example, the bypass control module 300 of FIG. 3) is provided for selecting the first transmission path or the second transmission path to transmit data, when the network system is turned off.

In some embodiments, in the step S403, the first transmission path or the second transmission path can be selected to serve as the data transmission path according to an operation of a user. In some other embodiments, the data transmission path can also be determined according to a state of the network system.

FIG. 5 is a flowchart illustrating a method for selecting a data transmission path according to a state of a network system. Referring to FIG. 5, in step S501, whether the network system is abnormal (for example, instable of input power or hardware malfunction) is determined. If there is no abnormal (i.e. “no” marked in the step S501 of FIG. 5), step S502 is then executed, namely, the former predetermined transmission path is maintained to perform the data transmission.

On the other hand, if it is determined that the system is abnormal according to the step S501 (i.e. “yes” marked in the step S501 of FIG. 5), step S503 is then executed, by which the time is counted to generate a time counting value. Now, in step S504, whether the time counting value reaches a predetermined time is determined, and if yes, the physical logical circuit then selects the first transmission path for transmitting data.

Though in the step S504, when the time counting value reaches the predetermined time, the physical logical circuit selects the first transmission path. However, it should be understand by those skilled in the art that the physical logical circuit can also select the second transmission path for transmitting data, which is not limited by the present invention.

In summary, since the present invention provides a physical logical circuit to control states of the switching modules, miss operation of the switching modules can be avoided when the system is turned off or the power is suddenly disappeared.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A bypass control module, for switching a plurality of data transmission paths within a network system, and the bypass control module comprising:
a logic circuit, for generating a logic output signal according to a state of a system power received by the network system and a state of at least one first control signal; and
a condition circuit, coupled to the logic circuit for outputting a condition signal, and determining a state of the logic circuit according to a state of the logic output signal,
wherein the network system selects one of the data transmission paths according to the state of the logic circuit for transmitting data.

2. The bypass control module as claimed in claim 1, wherein the logic circuit further determines the state of the logic output signal according to a state of a second control signal.

3. The bypass control module as claimed in claim 2, wherein the logic circuit comprises:
an OR gate, receives the first control signal and the second control signal respectively, and outputs an OR gate signal; and
a D flip-flop, having a flip-flop input terminal coupled to the OR gate for receiving the OR gate signal, a clock terminal receiving the system power, and a flip-flop output terminal and when the state of the system power is switched from a high level to a low level, the OR gate signal is output from the flip-flop output terminal to the condition circuit to serve as the logic output signal.

4. The bypass control module as claimed in claim 1, wherein the condition circuit comprises a transistor having a source coupled to the ground, a gate receiving the logic output signal, and a drain outputting the condition signal.

5. A network management apparatus for a network system, for connecting a plurality of client hosts to a server, the network management apparatus comprising:
a logic circuit, for generating a logic output signal according to a state of a system power and a state of at least one first control signal;
a condition circuit, coupled to the logic circuit for outputting a condition signal, and determining a state of the logic circuit according to a state of the logic output signal; and
a plurality of switching modules, respectively coupled to the client hosts and the server, and respectively having a first transmission terminal and a plurality of second transmission terminals, each of the switching modules being coupled to a next switching module via the second transmission terminals, and the switching modules being further coupled to the condition circuit for determining whether or not to couple the first transmission terminal of each switching module to one of the second transmission terminals of each switching module according to a state of the condition signal.

6. The network management apparatus as claimed in claim 5, wherein the logic circuit further determines the state of the logic output signal according to a state of a second control signal.

7. The network management apparatus as claimed in claim 6, wherein the
an OR gate, receives the first control signal and the second control signal respectively, and outputs an OR gate signal; and
a D flip-flop, having a flip-flop input terminal coupled to the OR gate for receiving the OR gate signal, a clock terminal receiving the system power, and a flip-flop output terminal and when the state of the system power is switched from a high level to a low level, the OR gate signal is output from the flip-flop output terminal to the condition circuit to serve as the logic output signal.

8. The network management apparatus as claimed in claim 6 further comprises:
a motherboard controller, for determining whether or not to output the first control signal according to an operation of a user; and
an input output control unit, having a counter for counting time when the network system is abnormal, and when a counted time reaches a predetermined time, the input output control unit outputs the second control signal.

9. The network management apparatus as claimed in claim 5, wherein the first transmission terminal of each of the switching modules is coupled to one of the client hosts via an RJ 45 interface.

10. The network management apparatus as claimed in claim 5 further comprises:
a plurality of converters, respectively coupled to the switching modules via one of the second transmission terminals of each of the switching modules; and
a transceiving unit, coupled to the converters via an interface, and coupled to the server.

11. The network management apparatus as claimed in claim 10, wherein the interface is a media-related interface (MDI).

12. A method for managing a network system, the network system being operated according to a system power, and the method comprising:
providing a plurality of first transmission paths for connecting a plurality of client hosts to a server;
providing a plurality of second transmission paths for mutually connecting the client hosts;
providing a physical logical circuit; and
when the network system is turned off, the physical logical circuit selecting the first transmission path or the second transmission path for transmitting data.

13. The method for managing a network system as claimed in claim 12, wherein step of judging whether or not the network system is turned off comprises detecting whether a state of the system power is switched from a high level to a low level.

14. The method for managing a network system as claimed in claim 12, wherein when the network system is turned off, the physical logical circuit further selects the first transmission path or the second transmission path according to an operation of a user for transmitting data.

15. The method for managing a network system as claimed in claim 12 further comprising:
determining whether or not the network system is abnormal;
starting to count time if the network is abnormal; and
when a counted time reaches a predetermined time, the physical logical circuit selecting the first transmission path for transmitting data.
